(19) United States
(12) Patent Application Publication
(10) Pub. No.: US 2019/0378854 A1
(43) Pub. Date: Dec. 12, 2019

(54) SEMICONDUCTOR DEVICE AND METHOD OF MANUFACTURING THE SAME USING PRELIMINARY SACRIFICIAL LAYERS

(71) Applicant: SAMSUNG ELECTRONICS CO., LTD., SUWON-SI (KR)

(72) Inventors: WOON KYUNG LEE, SEONGNAM-SI (KR); YOUN JOUNG CHO, HWASEONG-SI (KR)

(21) Appl. No.: 16/218,259

(22) Filed: Dec. 12, 2018

(30) Foreign Application Priority Data
Jun. 12, 2018 (KR) 10-2018-0067713

(51) Int. Cl. H01L 27/11582; H01L 27/11556; H01L 27/11565; H01L 27/11519

(52) U.S. Cl. CPC H01L 27/11582; H01L 27/11519; H01L 27/11565; H01L 27/11556

(57) ABSTRACT

A method of manufacturing a semiconductor device includes forming a preliminary stacked structure by alternately stacking mold insulating layers and preliminary sacrificial layers on a substrate, forming channel holes passing through the preliminary stacked structure, and converting the preliminary sacrificial layers into sacrificial layers through the channel holes, and the sacrificial layers have thicknesses greater than thicknesses of the preliminary sacrificial layers.

### CROSS-REFERENCE TO RELATED APPLICATION

This application claims priority to Korean Patent Application No. 10-2018-0067713 filed on Jun. 12, 2018 in the Korean Intellectual Property Office, the disclosure of which is herein incorporated by reference in its entirety.

### BACKGROUND

### 1. Technical Field

The present disclosure relate to a semiconductor device and a method of manufacturing the same using preliminary sacrificial layers.

### 2. Description of Related Art

Semiconductor devices of reduced size and equipped to perform high capacity processing are in demand. A semiconductor device having a vertical transistor structure in place of a conventional planar transistor structure has been proposed as one such method of increasing a degree of integration of semiconductor devices.

### SUMMARY

Exemplary embodiments of the present inventive concept provide for a method for manufacturing a semiconductor device which is capable of reducing manufacturing costs, and having a large number of layers with a high degree of integration.

According to an exemplary embodiment of the present inventive concept, a method of manufacturing a semiconductor device includes forming a preliminary stacked structure by alternately stacking mold insulating layers and preliminary sacrificial layers on a substrate. Channel holes passing through the preliminary stacked structure are formed. The preliminary sacrificial layers are converted into sacrificial layers through the channel holes. The sacrificial layers have thicknesses greater than the relative thicknesses of the preliminary sacrificial layers.

According to an exemplary embodiment of the present inventive concept, a method of manufacturing a semiconductor device includes alternately stacking first material layers and second material layers on a substrate. Channel holes are formed passing through the first material layers and the second material layers. Converting at least one of the first material layers or the second material layers into third material layers through the channel holes. The third material layers have thicknesses greater than the relative thickness of one of the first material layers and/or the second material layers.

According to an exemplary embodiment of the present inventive concept, a semiconductor device has a gate structure including mold insulating layers and gate electrodes alternately disposed on a substrate. Channel structures contact the substrate while passing through the gate structure. A side surface of the mold insulating layers contacts the channel structures and protrudes further than a side surface of the gate electrodes.

### BRIEF DESCRIPTION OF DRAWINGS

The aforementioned and other aspects of the present inventive concept will be more clearly understood from the following detailed description, observed in conjunction with the accompanying drawings, in which:

FIG. 1 is an equivalent circuit diagram illustrating a memory cell array of a semiconductor device according to an exemplary embodiment of the present inventive concept;

FIG. 2 is a plan view illustrating a semiconductor device according to an exemplary embodiment of the present inventive concept;

FIG. 3 is a cross sectional view illustrating a semiconductor device according to an exemplary embodiment of the present inventive concept;

FIGS. 4A and 4B are illustrations of an enlarged view of region ‘A’ and region ‘B’ of FIG. 3 according to an exemplary embodiment of the present inventive concept;

FIGS. 5A and 5B are enlarged cross-sectional views illustrating region ‘A’ and region ‘B’ of FIG. 3 according to an exemplary embodiment of the present inventive concept;

FIGS. 6 to 17 are drawings illustrating a method of manufacturing a semiconductor device according to an exemplary embodiment of the present inventive concept;

FIGS. 18 to 21 are drawings illustrating a method of manufacturing a semiconductor device according to an exemplary embodiment of the present inventive concept;

FIG. 22 is a cross-sectional view illustrating a semiconductor device according to an exemplary embodiment of the present inventive concept; and

FIGS. 23 to 26 are drawings illustrating a method of manufacturing a semiconductor device according to an exemplary embodiment of the present inventive concept.

### DETAILED DESCRIPTION

Exemplary embodiments according to the present inventive concept will be described in detail hereafter with reference to corresponding figures. In the drawings, the size of elements may be exaggerated for purposes of clarity, but are not necessarily limited thereto. It shall be understood that like reference numerals may refer to like elements throughout the accompanying drawings.

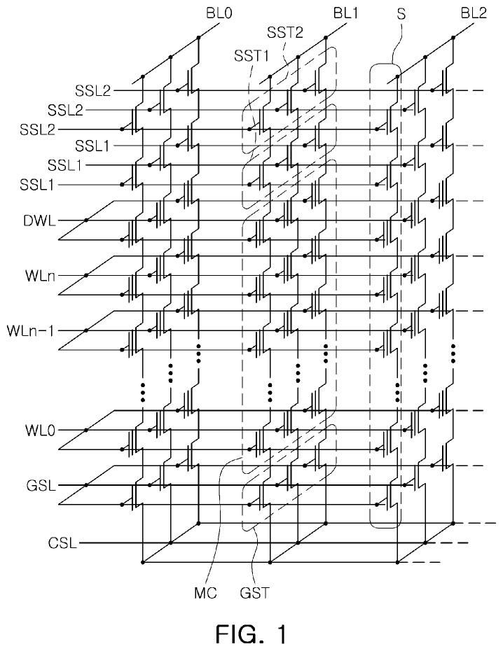

FIG. 1 is an equivalent circuit diagram of a memory cell array of a semiconductor device according to an exemplary embodiment of the present inventive concept.

Referring to FIG. 1, each memory cell array may include a plurality of memory cell strings S, each of which includes memory cells MC connected to each other in series. A ground select transistor GST and string select transistors SST1 and SST2 may be connected to both ends of the memory cells MC in series. The plurality of memory cell strings S may be connected to respective bit lines BL0 to BL2 in parallel. The plurality of memory cell strings S may be connected to a common source line CSL. For example, the plurality of memory cell strings S may be disposed between the plurality of bit lines BL0 to BL2 and a single common source line CSL. In an exemplary embodiment of the present inventive concept, a plurality of common source lines CSL may be arranged two-dimensionally.

The memory cells MC, connected to each other in series, may be controlled by word lines WL0 to WLn for selecting the memory cells MC. Each of the memory cells MC may include a data storage element. Gate electrodes of the memory cells MC arranged at substantially the same distance from the common source line CSL may be commonly connected to one of the word lines WL0 to WLn. In an exemplary embodiment of the present inventive concept, the gate electrodes of the memory cells MC arranged at substantially the same distance from the common source line CSL may be independently controlled, even when disposed in different rows and/or columns.

The ground select transistor GST may be controlled by a ground select line GSL, and may be connected to a common source line CSL. The string select transistors SST1 and SST2 may be controlled by the string select lines SSL1 and SSL2, and may be connected to the bit lines BL0 to BL2. FIG. 1 illustrates a structure according to an exemplary embodiment in which a single ground select transistor GST and two string select transistors SST1 and SST2 are connected to the plurality of memory cells MC connected in series. According to an exemplary embodiment of the present inventive concept, the memory cells MC may be connected to a single string select transistor SST1 and/or a plurality of ground select transistors GST. One or more dummy lines DWL or buffer lines may further be disposed between an uppermost word line WLn, among the word lines WL0 to WLn, and/or the string select transistors SST1 and SST2. According to an exemplary embodiment of the present inventive concept, one or more dummy lines DWL may also be disposed between a lowermost word line WL0 and the ground select line GSL.

When a signal is applied to the string select transistors SST1 and SST2 through the string select lines SSL1 and SSL2, a signal applied through the bit lines BL0, BL1, and BL2 may be transmitted to the memory cells MC connected to each other in series. A data reading operation and a data writing operation may be performed. An erasing operation for erasing data written on the memory cells MC may also be performed by applying a predetermined erasing voltage through a substrate. According to an exemplary embodiment of the present inventive concept, the memory cell array may include at least one dummy memory cell string electrically isolated from the bit lines BL0 to BL2.

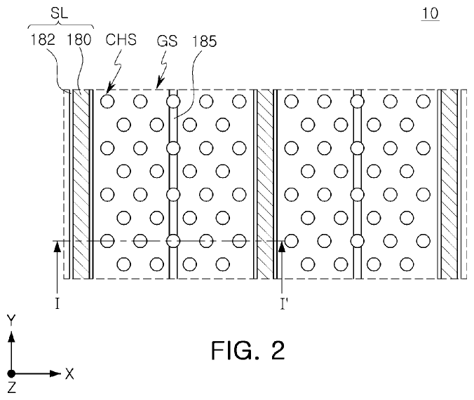

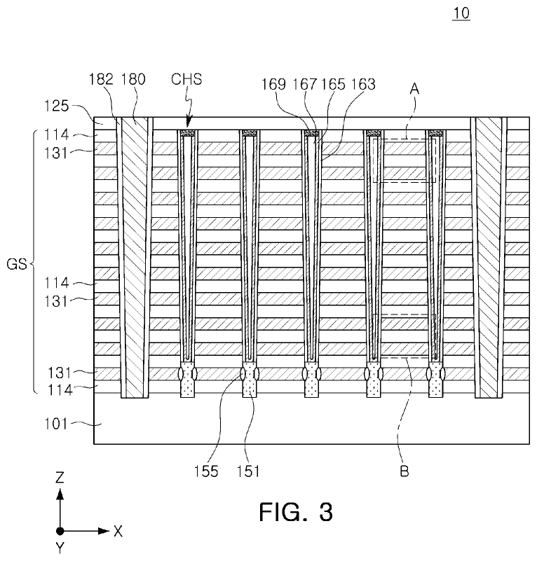

FIGS. 2 and 3 are a plan view and a cross-sectional view illustrating a semiconductor device according to an exemplary embodiment of the present inventive concept. FIG. 3 is a cross sectional view taken along line I-I′ of FIG. 2. Referring to FIGS. 2 and 3, a semiconductor device 10 may include a substrate 101. Gate structures GS are disposed on the substrate 101 and include gate electrodes 131. Channel structures CHS extend in a direction perpendicular to an upper surface of the substrate 101 passing through the gate structures OS. Separation regions SL and the gate structures GS are alternatively disposed on the substrate 101.

The gate structure GS may include mold insulating layers 114 and gate electrodes 131 alternately stacked. The number of gate electrodes 131 and the number of mold insulating layers 114 may be variously changed.

Each of the channel structures CHS includes a channel layer 165. A gate dielectric layer 163 is disposed between the channel layer 165 and the gate electrodes 131. Channel pads 169 are disposed on an upper end of the channel structures CHS, and a channel insulating layer 167 fills an interior of the channel layer 165.

The separation regions SL may include a source conductive layer 180 and a source insulating layer 182 covering the conductive layer 180. As illustrated in FIG. 2, the gate structures GS may be spaced apart from each other in an X-direction by the separation regions SL which extend in a Y-direction.

In the semiconductor device 10, a single memory cell string may be provided along each of the channel structures CHS, and the plurality of memory cell strings may be arranged in rows and columns in the X-direction and the Y-direction, respectively.

The plurality of gate electrodes 131 may be spaced apart from each other in a Z-direction perpendicular to an upper surface of the substrate 101 along a side surface of each of the channel structures CHS. The plurality of gate electrodes 131 may also extend in the Y-direction. The gate electrodes 131 may provide gate electrodes of the ground select transistor GST, the plurality of memory cells MC, and the string select transistors SST1 and SST2 of FIG. 1. The gate electrodes 131 may extend to provide gate electrodes to the word lines WL0 to WLn, the string select lines SSL1 and SSL2, and the ground select line GSL. The word lines WL0 to WLn may be commonly connected in adjacent memory cell strings S in a predetermined unit arranged in the X-direction and the Y-direction. The gate electrodes 131, providing the string select lines SSL1 and SSL2 may be divided into two regions in the X-direction by the insulating layer 185.

The substrate 101 may have an upper surface extended in both the X-direction and the Y-direction. The substrate 101 may include a semiconductor material, such as a Group IV semiconductor, a Group III-V compound semiconductor, or a Group II-VI compound semiconductor. For example, the Group IV semiconductor may include silicon, germanium, and/or silicon-germanium. The substrate 101 may be provided as a bulk wafer or an epitaxial layer. The substrate 101 may be formed of single crystal silicon or polycrystalline silicon. The substrate 101 may include n-type or a p-type impurities.

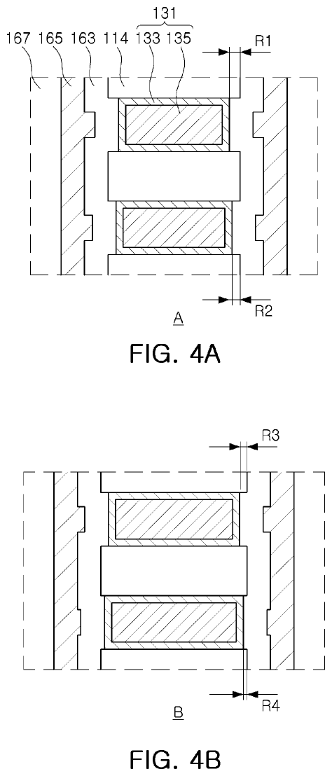

The gate electrodes 131 may include a first conductive layer 133 and a second conductive layer 135 (referring to FIG. 4A). The first conductive layer 133 may be disposed between the second conductive layer 135 and the mold insulating layer 114 and between the second conductive layer 135 and the gate dielectric layer 163.

The first conductive layer 133 may include a tungsten nitride (WN), a tantalum nitride (TaN), a titanium nitride (TiN), and/or combinations thereof. The second conductive layer 135 may contain a metal silicide material, or a metal material. The metal material may include, for example, tungsten (W).

The mold insulating layers 114 may be disposed between the gate electrodes 131. The mold insulating layers 114 may be spaced apart from each other in the Z-direction perpendicular to an upper surface of the substrate 101 and may extend in the Y-direction, in a manner similar to the gate electrodes 130. The mold insulating layers 114 may include an insulating material such as a silicon oxide and/or a silicon nitride.

FIGS. 4A and 4B are enlarged illustrations of region ‘A’ and region ‘B’ of FIG. 3.

Region ‘A’ of FIG. 4A illustrates a portion of an upper region of a gate structure GS, and region ‘B’ of FIG. 4B illustrates a portion of a lower region of the gate structure GS.

Referring to FIGS. 4A and 4B, a side surface of the mold insulating layers 114 in contact with the channel structures CHS may protrude further in a horizontal direction relative to side surfaces of the gate electrodes 131.

A protrusion length of the mold insulating layers 114 may decrease in a direction from an upper portion to a lower portion of the gate structure GS toward the substrate 101. A horizontal separation distance between side surfaces of the gate electrodes 131 from side surfaces of the mold insulating layers 114 may decrease in a direction from the upper portion to the lower portion of the gate structure GS towards the substrate 101. In FIGS. 4A and 4B, the relative sizes of the protrusion lengths are as follows: a first protrusion length R1>a second protrusion length R2>a third protrusion length R3>a fourth protrusion length R4.

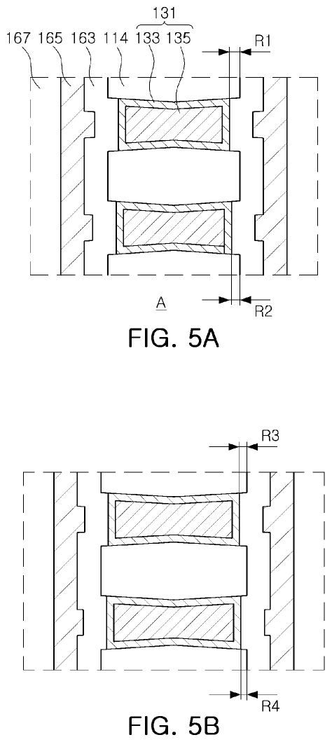

FIGS. 5A and 5B are cross-sectional views of a semiconductor device according to an exemplary embodiment of the present inventive concept. Similar to FIGS. 4A and 4B, region ‘A’ of FIG. 5A illustrates an enlarged portion of the upper region of the gate structure GS, and region ‘B’ of FIG. 5B illustrates an enlarged portion of the lower region of the gate structure GS.

FIGS. 5A and 5B are similar to FIGS. 4A and 4B except that, according to an exemplary embodiment, gate electrodes 131 and the mold insulating layers 114 may be shapes other than rectangular. In FIGS. SA and SB, thicknesses of the gate electrodes 131 increase in a horizontal direction toward the channel structures CHS. Thicknesses of the mold insulating layers 114 may decrease in a horizontal direction towards the channel structures CHS.

The channel structures CHS may be disposed on the substrate 101 in rows and columns that are spaced apart from each other, while passing vertically through the gate structures GS. The channel structures CHS may be disposed in the formation of a grid or may be arranged in a zigzag formation in one direction. The channel structures CHS may extend in the Z-direction perpendicular to an upper surface of the substrate 101.

The channel structures CHS may have a side surface perpendicular to the substrate 101, or may have an inclined side surface with a narrower width in a direction extending toward the substrate 101. In the channel structures CHS, the channel layer 165 may have an annular shape surrounding the channel insulating layer 167, formed therein. However, the channel layer 165 may have a columnar shape without the channel insulating layer 167, such as a cylinder or a prism, according to an exemplary embodiment of the present inventive concept. The channel layer 165 may be in contact with an epitaxial layer 151 on the substrate 101, and may be connected to the substrate 101 through the epitaxial layer 151. According to exemplary embodiments of the present inventive concept, the channel layer 165 might not be connected to the substrate 101 through the epitaxial layer 151 on the substrate 101, but may be directly connected to the substrate 101. The channel layer 165 may contain a semiconductor material such as polycrystalline silicon or single crystal silicon, and the semiconductor material may be an undoped material, or a material containing p- or n-type impurities. A channel pad 169 may be disposed on an upper end of the channel layer 165 in the channel structures CHS. The channel pad 169 may be electrically connected to the channel layer 165 while covering an upper surface of the channel insulating layer 167. The channel pads 169 may include, for example, doped polycrystalline silicon.

The channel structures CHS may be connected to bit lines BL0 to BL2 by a contact plug connected to the channel pad 169. Moreover, a portion among the channel structures CHS disposed in a position overlapping the insulating layer 185, may be a dummy channel structure not electrically connected to the bit lines BL0 to BL2.

The gate dielectric layer 163 may be disposed between the gate electrodes 131 and the channel layer 165. The gate dielectric layer 163 may include a tunneling layer, a charge storage layer, and a blocking layer, sequentially stacked from the channel layer 165. The tunneling layers may include a silicon oxide (SiO₂), a silicon nitride (Si₃N₄), a silicon oxynitride (SiON) and/or combinations thereof. The charge storage layer may be a charge trapping layer or a floating gate conductive layer. According to exemplary embodiments of the present inventive concept, when the charge storage layer is a charge trapping layer, the charge storage layer may include a silicon nitride. The blocking layer may include, for example, a silicon oxide (SiC₂), a silicon nitride (Si₃N₄), a silicon oxynitride (SiON), a high-k dielectric material, and/or combinations thereof. In exemplary embodiments of the present inventive concept, at least a portion of the blocking layer may extend in a horizontal direction along the gate electrodes 131.

Insulating layers 155 may be disposed between epitaxial layers 151 and a gate electrode 131 disposed in a lowermost portion of the gate structure GS.

Separation regions SL may pass through the gate structure GS to be connected to the substrate 101 and disposed between the channel structures CHS. The source conductive layer 180 may be spaced apart and electrically insulated from the gate electrodes 131 by a source insulating layer 182. Thus, the gate electrodes 131 may be separated from each other at predetermined intervals in the X-direction with the source conductive layer 180 interposed there between. The source conductive layer 180 may be disposed in the form of a line extended in the Y-direction, and may correspond to the common source line CSL, described previously with reference to FIG. 1. The source conductive layer 180 may be disposed at predetermined intervals in the X-direction. The source conductive layer 180 may have a width that decreases in a direction towards the substrate 101. The source conductive layer 180 may have a side surface perpendicular to an upper surface of the substrate 101. According to exemplary embodiments of the present inventive concept, an impurity region may be disposed in the substrate 101 in contact with the source conductive layer 180.

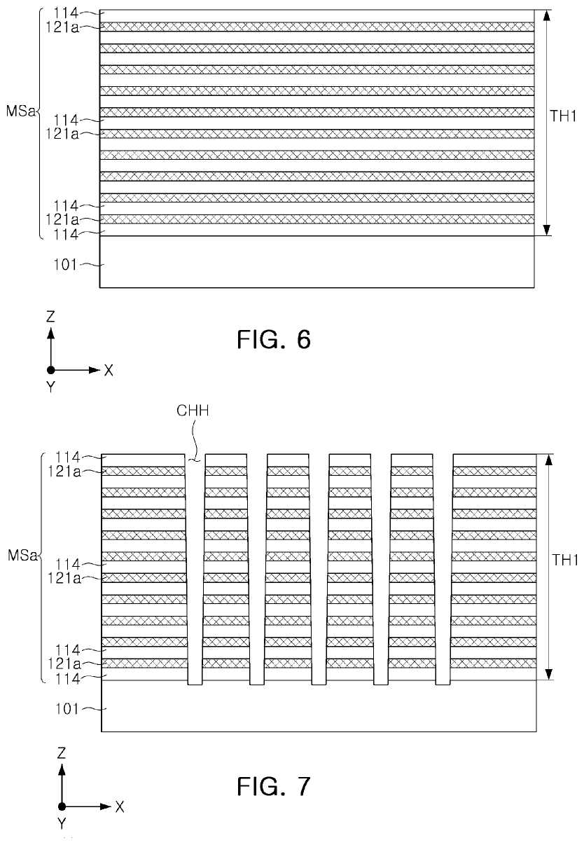

FIGS. 6 to 17 are drawings illustrating a method of manufacturing a semiconductor device according to an exemplary embodiment of the present inventive concept. A method of manufacturing a semiconductor device 10 of FIG. 2 will be described.

Referring to FIG. 6, a preliminary stacked structure MSa in which mold insulating layers 114 and preliminary sacrificial layers 121a are alternately stacked on a substrate 101 may be provided. A mold insulating layer 114 may be disposed on an uppermost portion of the preliminary stacked structure MSa furthest from the substrate 101.

The preliminary sacrificial layers 121a may be converted into sacrificial layers 121 through a subsequent process. The preliminary sacrificial layers 121a may be formed of a material different from that of the mold insulating layers 114.

For example, the mold insulating layer 114 may be formed of a silicon nitride and/or a silicon oxide. The preliminary sacrificial layers 121a may be formed of polycrystalline silicon, polycrystalline germanium, and/or combinations thereof. In an exemplary embodiment of the present inventive concept, the preliminary sacrificial layers 121a may be formed of a polymer. The polymer may be formed of polydimethylsiloxane (PDMS). In an exemplary embodiment of the present inventive concept, the preliminary sacrificial layers 121a may be formed of a material having a lamellar structure. The preliminary sacrificial layers 121a may be formed of, for example, a material mainly composed of graphite. The preliminary sacrificial layers 121a may be formed of, for example, a phyllosilicate material.

The mold insulating layers 114 and the preliminary sacrificial layers 121a may be formed using an atomic layer deposition (ALD) process, a chemical vapor deposition (CVD) process, a spin coating process, or the like.

The thicknesses and the number of the mold insulating layers 114 and the preliminary sacrificial layers 121a may be variously changed from those illustrated in the drawings.

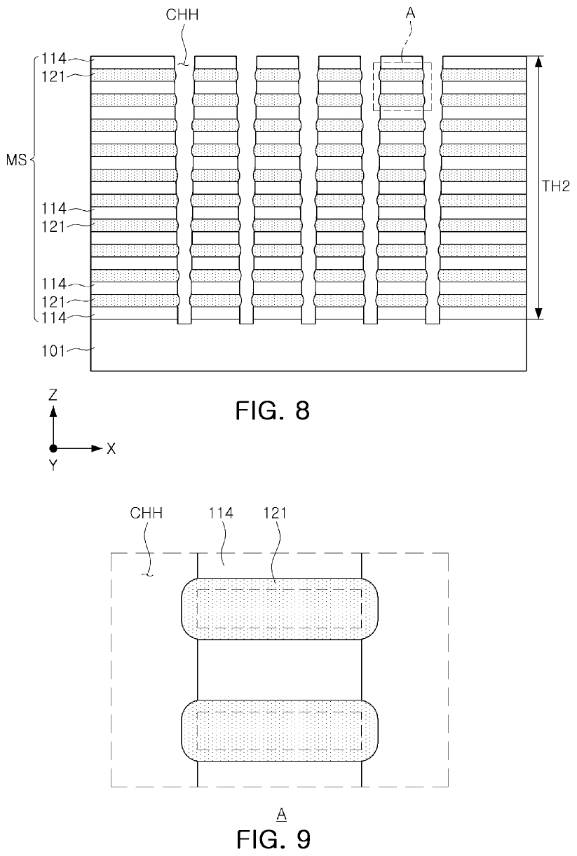

The thicknesses of the preliminary sacrificial layers 121a are smaller than thicknesses of the sacrificial layers 121 to be formed through a subsequent process. Thus, a thickness TH1 of the preliminary stacked structure MSa is smaller than a thickness TH2 of FIG. 8 of a stacked structure MS ultimately to be obtained.

Referring to FIG. 7, channel holes CHH passing through the preliminary stacked structure MSa may be formed.

The channel holes CHH may be provided by anisotropically etching the preliminary stacked structure MSa, after a mask layer is formed using a photolithography process. The channel holes CHH may be formed in the form of a hole. A side wall of the channel holes CHH might not be perpendicular to an upper surface of the substrate 101. According to an exemplary embodiment of the present inventive concept, anisotropic etching may be used to form the channel holes CHH. Recesses may be formed in an upper surface of the substrate 101.

A first thickness TH1 of the preliminary stacked structure MSa is smaller than a second thickness TH2 of the stacked structure MS of FIG. 8. An aspect ratio of the channel holes CHH is thus reduced, and an anisotropic etching process for forming the channel holes CHH may be more easily performed.

Referring to FIG. 8, a stacked structure MS may be provided in which mold insulating layers 114 and sacrificial layers 121 are alternately stacked.

The preliminary sacrificial layers 121a from prior FIGS. 6 and 7 may be converted into the sacrificial layers 121 using a volume expansion process through the channel holes CHH. In an exemplary embodiment, when the preliminary sacrificial layers 121a are formed of polycrystalline silicon, for example, the volume expansion process may include a wet or dry oxidation process. As a source of oxygen is injected into the channel holes CHH, the polycrystalline silicon may be oxidized. The source of oxygen may include water vapor, oxygen gas, oxygen radicals, and/or combinations thereof.

In an exemplary embodiment, the preliminary sacrificial layers 121a are formed of, for example, polydimethylsiloxane (PDMS). The volume expansion process may include injecting 1-bromododecane through the channel holes CHH to react with the polydimethylsiloxane (PDMS).

According to an exemplary embodiment, when the preliminary sacrificial layers 121a are formed of a material having a lamellar structure, the volume expansion process may form an interlayer compound.

Due to the volume expansion process, a thickness TH2 of the stacked structure MS is greater than a thickness TH1 of the preliminary stacked structure MSa of FIG. 6.

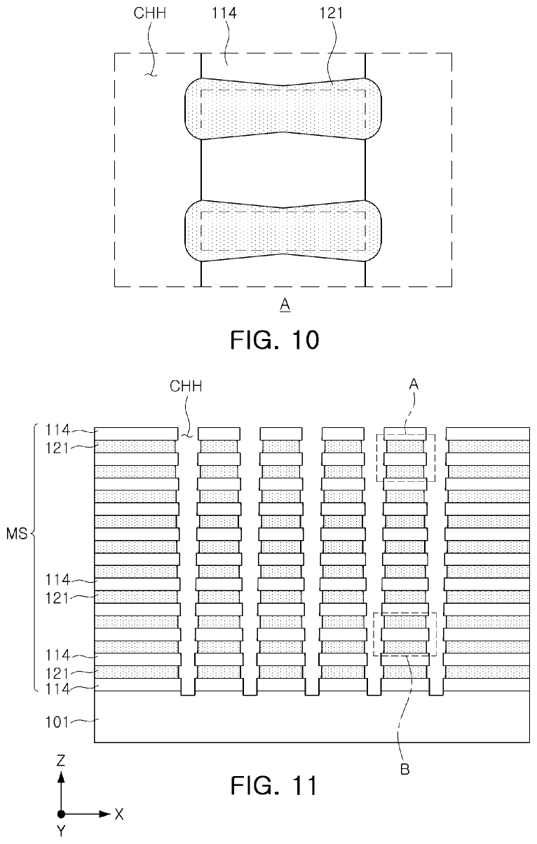

Referring to FIGS. 9 and 10, the sacrificial layers 121 formed using the volume expansion process may protrude further than a side surface of the mold insulating layers 114 toward the channel holes CHH. Due to the volume expansion process, the preliminary sacrificial layers 121a may expand not only vertically but also horizontally.

Referring to FIG. 10, in an exemplary embodiment of the present inventive concept, the sacrificial layers 121 may have a thickness increased in a direction toward the channel holes CHH. The sacrificial layers 121 may have a thickness reduced in a direction away from the channel holes CHH. The mold insulating layers 114 may have a thickness reduced toward the channel holes CHH. The mold insulating layers 114 may have a thickness increased in a direction away from the channel holes CHH.

Referring to FIG. 11, a portion of the sacrificial layers 121 protruding into an interior of the channel holes CHH may be removed by a wet etching or dry etching process. In the operation described above, a side surface of the mold insulating layers 114 may protrude further in a horizontal direction toward the channel holes CHH than a side surface of the sacrificial layers 121.

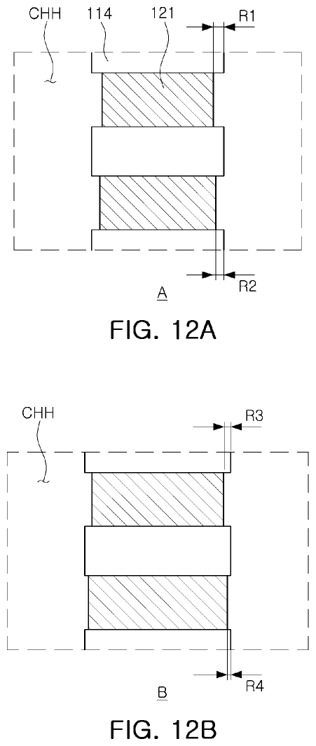

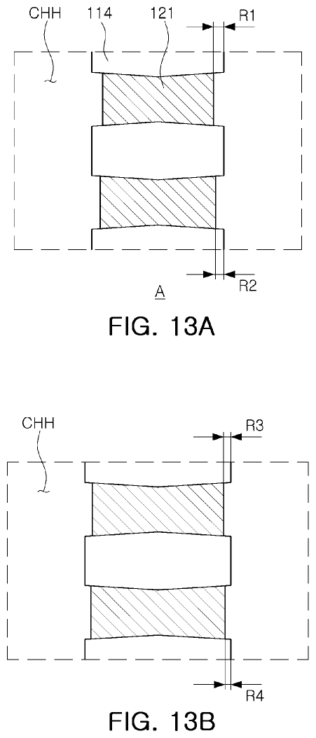

In FIGS. 12A, 12B, 13A and 13B, region ‘A’ illustrates a portion of an upper region of a gate structure GS, and region ‘B’ illustrates a portion of a lower region of the gate structure GS.

Referring to FIGS. 12A, 12B, 13A and 13B, a protrusion length of the mold insulating layers 114 may decrease from an upper portion to a lower portion of the gate structure GS in a direction towards the substrate 101. A horizontal separation distance between side surfaces of the insulating layers 114 and the side surfaces of the sacrificial layers 121 may decrease from the upper portion of the gate structure GS towards the lower portion in a direction towards the substrate 101. In FIGS. 12A, 12B, 13A and 13B, the relationship of a first protrusion length R1>a second protrusion length R2>a third protrusion length R3>a fourth protrusion length R4 is satisfied.

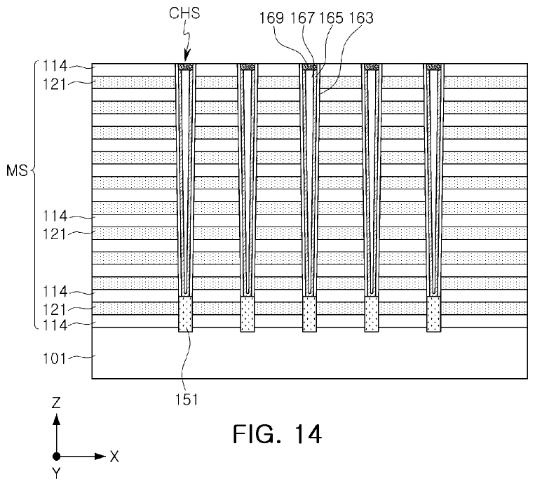

Referring to FIG. 14, channel structures CHS may be provided by forming an epitaxial layer 151, a gate dielectric layer 163, a channel layer 165, a channel insulating layer 167, and a channel pad 169 in the channel holes CHH.

The epitaxial layer 151 may be formed using a selective epitaxial growth (SEG) process in which a substrate 101 exposed by channel holes CHH is used as a seed. The gate dielectric layer 163 may be formed using an atomic layer deposition (ALD) or chemical vapor deposition (CVD) process to have a uniform thickness. In the operation described above, at least a portion of the gate dielectric layer 163 may be extended substantially perpendicular to the substrate 101 along the channel holes CHH. The channel layer 165 may be formed on the gate dielectric layer 163 in the channel holes CHH. A lower end of the channel layer 165 may contact the epitaxial layer 151. According to an exemplary embodiment of the present inventive concept, the epitaxial layer 151 might not be provided, and the channel layer 165 may therefore directly contact the substrate 101. The channel insulating layer 167 may fill remaining spaces of the channel holes CHH, and may include an insulating material. However, according to an exemplary embodiment of the present inventive concept, a space between the channel layers 165 may be filled with a conductive material rather than the channel insulating layer 167. The channel pad 169 may be formed of a conductive material, for example, polycrystalline silicon. The channel pad 169 may be in contact with an upper end of the channel layer 165.

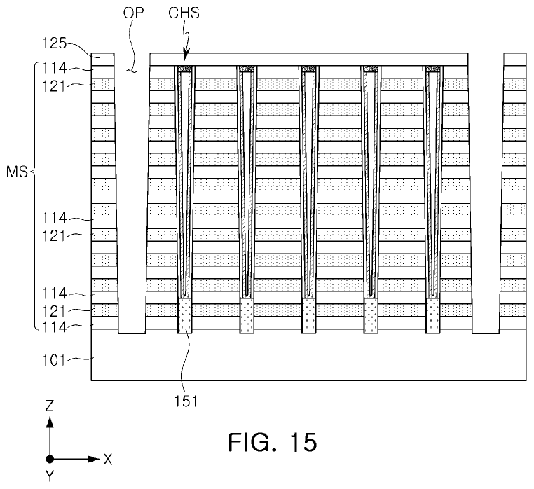

Referring to FIG. 15, openings OP passing through the stacked structure MS may be formed.

Before the openings OP are formed, an insulating layer 125 may be disposed to cover uppermost portions of both a mold insulating layer 114 and channel pads, thereby preventing damage to the channel structures CHS caused by a subsequent process. The openings OP may be provided as a mask pattern layer is formed using a photolithography process, and an insulating layer 125, sacrificial layers 121, and mold insulating layers 114 are anisotropically etched. The openings OP may be repeatedly arranged at predetermined intervals in the X-direction, and may be provided to pass through the stacked structure MS to expose the substrate 101. The opening OP is extended in the Y-direction in the form of a trench, and the stacked structure MS may be divided into a plurality of stacked structures by the openings OP. A side wall of the openings OP might not be perpendicular to an upper surface of the substrate 101.

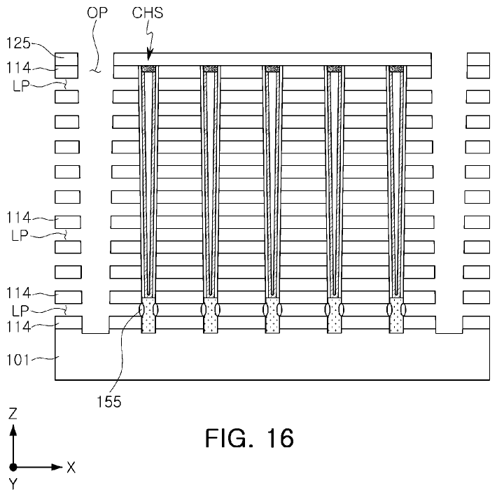

Referring to FIG. 16, the portions of the sacrificial layers 121 adjacent to the channel structures CHS may be removed through the openings OP.

The sacrificial layers 121 may be removed with respect to the mold insulating layers 114 using, for example, wet etching. Thus, a plurality of side openings LP may be formed between the mold insulating layers 114. A portion of the side walls of the channel structures CHS may be exposed through side openings LP. Moreover, a portion of the side walls of the epitaxial layers 151 may be exposed through the side openings LP. An insulating layer 155 may be provided on the exposed portion of the side walls of the epitaxial layers 151. The insulating layer 155 may be formed using a thermal oxidation process.

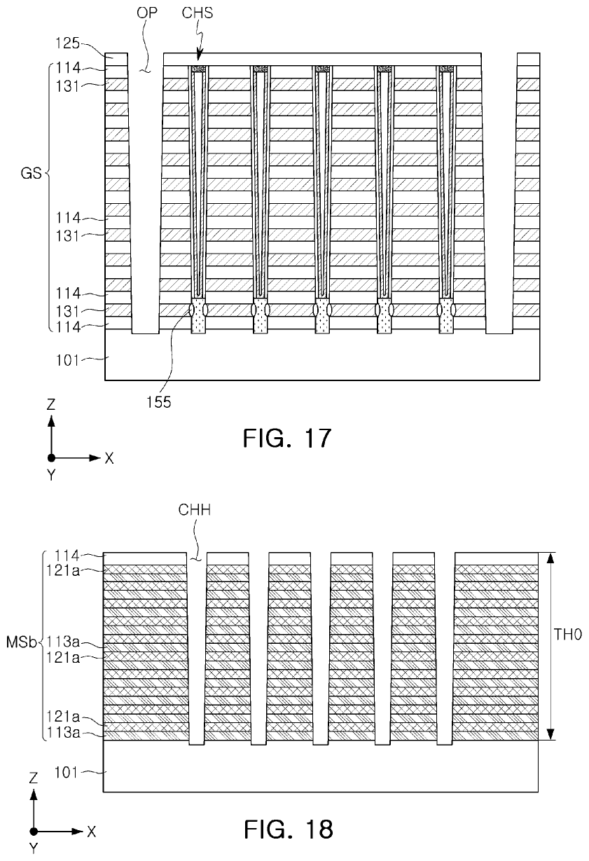

Referring to FIG. 17, gate electrodes 131 may be provided in a region from which the sacrificial layers 121 are removed.

The gate electrodes 131 may include at least one of a metal nitride, a metal, polycrystalline silicon, and/or a metal silicide. After a material forming the gate electrodes 131 is provided, the material formed in the openings OP may be removed through an additional process to allow the gate electrodes 131 to be disposed in the side openings LP. In an exemplary embodiment of the present inventive concept, mold insulating layers 114 may protrude further horizontally toward the openings OP than gate electrodes 131.

Side surfaces of the gate electrodes 131 may be provided in substantially the same plane. In the operation described above, the gate electrodes 131 are provided for the gate structures GS.

Referring back to FIG. 3, the source insulating layer 182 and the source conductive layer 180 are disposed in the opening OP, and a separation region SL may be formed.

The source insulating layer 182 may be provided in the form of a spacer. After the insulating material is deposited, insulating material is removed from the substrate 101 to expose an upper surface of the substrate 101.

Next, the source conductive layer 180 may be provided. A conductive material is deposited on the source insulating layer 182 and flattening is performed so that the exposed upper surface of the source insulating conductive layer 180 is coplanar with the exposed upper surface of the insulating layer 125. The gate electrodes 131 may be spaced apart from each other at a predetermined distance in the X-direction by the isolation region SL. The conductive material may include, for example, tungsten.

FIGS. 18 to 21 are drawings illustrating a method of manufacturing a semiconductor device according to an exemplary embodiment of the present inventive concept.

Referring to FIG. 18, a first preliminary stacked structure MSb may be formed in which preliminary mold material layers 113a and preliminary sacrificial layers 121a are alternately stacked on a substrate 101. A mold insulating layer 114 may be disposed on an uppermost portion furthest from the substrate 101.

The preliminary mold material layers 113a may be converted into mold material layers 113 through a subsequent process, and may then be replaced with a mold insulating layer 114. The preliminary sacrificial layers 121a may be converted into sacrificial layers 121 through a subsequent process. The preliminary mold material layers 113a may be formed of a material different from that of the preliminary sacrificial layers 121a.

In an exemplary embodiment of the present inventive concept, the preliminary mold material layer 113a may be formed of a polymer. The polymer may be formed of polydimethylsiloxane (PDMS). The preliminary sacrificial layers 121a may be formed of, for example, polysilicon.

The preliminary mold material layers 113a and the preliminary sacrificial layers 121a may be formed using an atomic layer deposition (ALD), a chemical vapor deposition (CVD), a spin coating process, or the like.

The thickness and the number of the preliminary mold material layers 113a and the preliminary sacrificial layers 121a may be variously changed from that which is illustrated in the drawings.

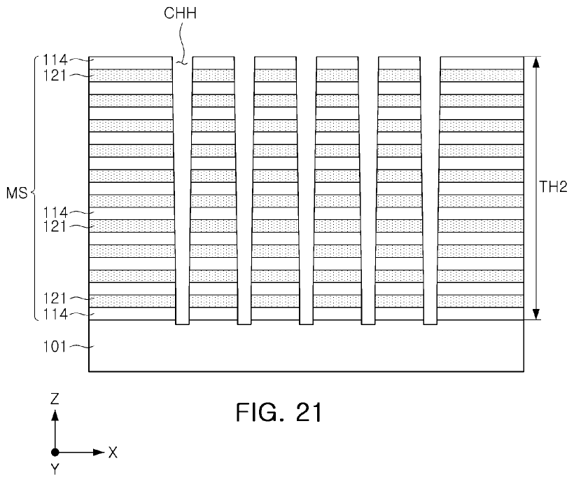

In an exemplary embodiment of the present inventive concept, a thickness of the preliminary mold material layers 113a is smaller than a thickness of the mold insulating layer 114 to be formed through a subsequent process. Similarly, the thickness of the preliminary sacrificial layers 121a is smaller than a thickness of the sacrificial layers 121 to be formed through a subsequent process. Thus, a thickness TH0 of the preliminary stacked structure MSb is smaller than a thickness TH2 of a stacked structure MS of FIG. 21.

Channel holes CHH passing through a first preliminary stacked structure MSb may be provided. The channel holes CHH may be provided by anisotropically etching the preliminary stacked structure MSb, after a mask layer is formed using a photolithography process. The channel holes CHH may be formed in the shape of a hole.

A thickness TH0 of the first preliminary stacked structure MSb is smaller than a relative thickness TH2 of the stacked structure MS of FIG. 21, so an aspect ratio of the channel holes CHH is therefore reduced. Thus, an anisotropic etching process for forming the channel holes CHH may be easily performed.

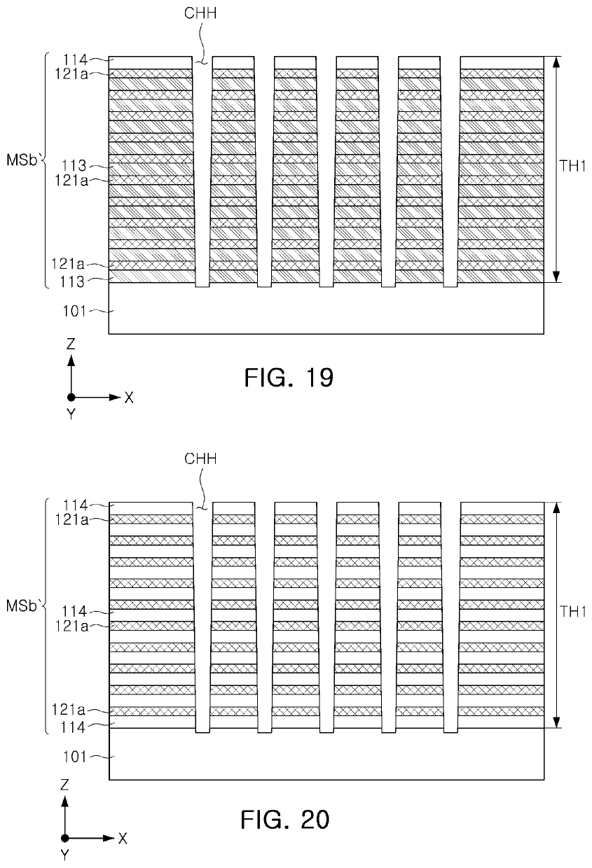

Referring to FIG. 19, a second preliminary stacked structure MSb′ may be formed, including mold material layers 113 and preliminary sacrificial layers 121a alternately stacked.

The preliminary mold material layer 113a may be converted into the mold material layer 113 using a volume expansion process through the channel holes CHH.

When the preliminary mold material layer 113a is formed of, for example, polydimethylsiloxane (PDMS), the volume expansion process may be a process in which 1-bromododecane is injected into the channel holes CHH to react with polydimethylsiloxane (PDMS). The mold material layer 113 may be a compound formed by reacting polydimethylsiloxane (PDMS) and 1-bromododecane with each other.

Due to the volume expansion process, a thickness TH1 of the second preliminary stacked structure MSb′ is greater than a thickness TH0 of the first preliminary stacked structure MSb of FIG. 18.

Referring to FIG. 20, a mold material layer 113 may be replaced with a mold insulating layer 114.

The mold material layer 113 is removed using a wet etching process. A space from which the mold material layer 113 was removed may be filled with a mold insulating layer 114. After a material forming the mold insulating layer 114 is deposited using, for example, an ALD process, a material forming the mold insulating layer 114 formed in the channel holes CHH may be removed through an additional etching process. The mold insulating layer 114 may be formed of, for example, a silicon nitride.

Referring to FIG. 21, a stacked structure MS in which mold insulating layers 114 and sacrificial layers 121 are alternately stacked may be formed.

The preliminary sacrificial layers 121a are converted into the sacrificial layers 121 using a volume expansion process through the channel holes CHH. When the preliminary sacrificial layers 121a are formed of, for example, polycrystalline silicon, the volume expansion process may be either a wet or dry oxidation process. Water vapor, oxygen gas, oxygen radicals, and/or combinations thereof may be injected into the channel holes CHH, so that the polycrystalline silicon may be oxidized.

Due to the volume expansion process, a thickness TH2 of the stacked structure MS is greater than a thickness TH1 of the second preliminary stacked structure MSb′ of FIG. 20.

Then, the operations described previously with reference to FIGS. 11 to 17 as well as FIG. 3 are performed, so that a semiconductor device 10 may be manufactured.

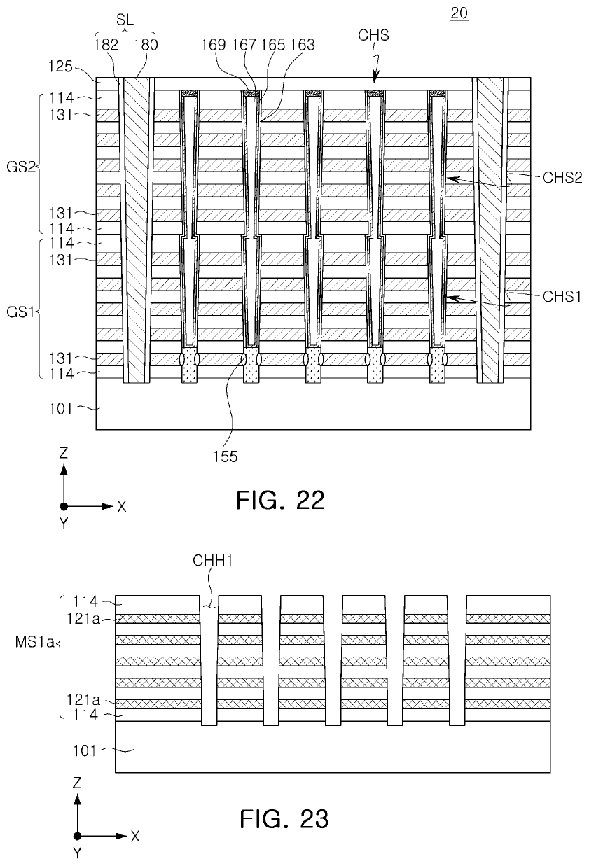

FIG. 22 is a cross-sectional view illustrating a semiconductor device 20 according to an exemplary embodiment of the present inventive concept.

Referring to FIG. 22, unlike the arrangement depicted in FIG. 3, the semiconductor device 20 includes a first gate structure GS1 and a second gate structure GS2, sequentially stacked on a substrate 101. Each of the first gate structure GS1 and the second gate structure GS2 may include mold insulating layers 114 and gate electrodes 131 alternately stacked. The channel structures CHS may include first channel structures CHS1 and second channel structures CHS2, sequentially stacked on the substrate 101. Each of the first channel structures CHS1 and the second channel structures CHS2 may include a channel layer 165, a gate dielectric layer 163 disposed between the channel layer 165 and the gate electrodes 131, and a channel insulating layer 150 filling an interior of the channel layer 165. The first channel structures CHS1 may include an epitaxial layer 151 in contact with a substrate 101, and the second channel structures CHS2 may include a channel pad 169 in contact with an upper end of the channel layer 165. The separation regions SL may include a source conductive layer 180 and a source insulating layer 182.

In the first channel structure CHS1 and the second channel structure CHS2, a channel layer 165 and a gate dielectric layer 163 may be disposed to be connected to each other. The vertically stacked first channel structure CHS1 and second channel structure CHS2 may have a single channel pad 169, and may include a single epitaxial layer 151. The channel layer 165 and the gate dielectric layer 163 may have a stepped portion at a boundary between the first channel structure CHS1 and the second channel structures CHS2, but are not limited thereto.

With reference to an exemplary embodiment according to FIGS. 4A, 4B, 5A and 5B, the description and associated elements may be similarly applied to a semiconductor device 20 of FIG. 22.

FIGS. 23 to 26 illustrate a method of manufacturing a semiconductor device 20 according to an exemplary embodiment of the present inventive concept.

Referring to FIG. 23, a first preliminary stacked structure MS1a is formed in which mold insulating layers 114 and preliminary sacrificial layers 121a are alternately stacked on a substrate 101. A mold insulating layer 114 may be disposed on an uppermost portion of the first preliminary stacked structure MS1a furthest from the substrate 101.

In addition, first channel holes CHH1 passing through the first preliminary stacked structure MS1a may be provided. A side wall of the first channel holes CHH1 might not be perpendicular to an upper surface of the substrate 101.

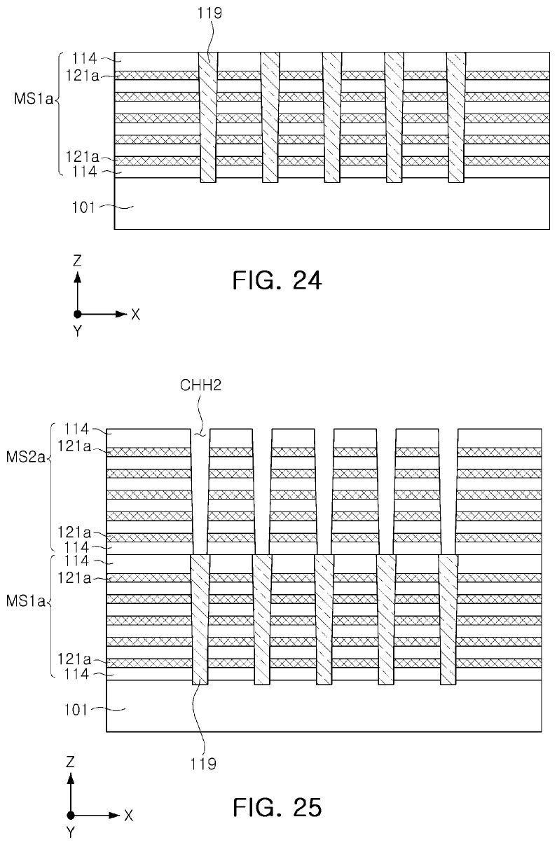

Referring to FIG. 24, first channel holes CHH1 may be filled with a gap-fill layer 119. After the gap-fill layer 119 is formed to fill the first channel holes CHH1, the material forming the gap-fill layer 119 may be removed to expose an upper surface of a mold insulating layer 114 using a flattening process.

Referring to FIG. 25, a second preliminary stacked structure MS2a may be formed. A second preliminary stacked structure MS2a may include mold insulating layers 114 and preliminary sacrificial layers 121a alternately stacked on the first preliminary stacked structure MS1a and the gap-fill layer 119. Second channel holes CHH2 passing through the second preliminary stacked structure MS2a may also be formed. A side wall of the second channel holes CHH2 might not be perpendicular to an upper surface of the substrate 101. The gap-fill layer 119, filling the first channel holes CHH1, may be exposed by the second channel holes CHH2.

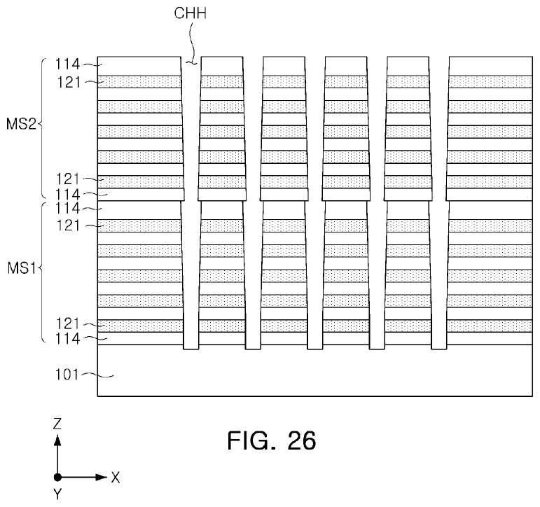

Referring to FIG. 26, a first stacked structure MS1 and a second stacked structure MS2 may be provided in which both include mold insulating layers 114 and sacrificial layers 121, alternately stacked.

The gap-fill layer 119 which is exposed by the second channel holes CHH2, is removed to form channel holes CHH passing through the first stacked structure MS1 and the second stacked structure MS2.

The preliminary sacrificial layers 121a may be converted into the sacrificial layers 121 using a volume expansion process introduced through the channel holes CHH.

Due to the volume expansion process, a thickness of the first stacked structures MS1 and the second stacked structures MS2 may be greater than a relative thickness of the first preliminary stacked structures MS1a and the second preliminary stacked structures MS2a, respectively.

While exemplary embodiments of the present inventive concept have been shown in accompanying figures and described above, it will be apparent to those skilled in the art that modifications and variations could be made without departing from the scope of the present disclosure, as defined by the appended claims.

What is claimed is:

1. A method of manufacturing a semiconductor device, comprising:
forming a preliminary stacked structure by alternately stacking mold insulating layers and preliminary sacrificial layers on a substrate;
forming channel holes passing through the preliminary stacked structure; and
converting the preliminary sacrificial layers into sacrificial layers using the channel holes,
wherein each of the sacrificial layers has a thickness that is greater than a thickness of each of the preliminary sacrificial layers.

2. The method of manufacturing a semiconductor device of claim 1, wherein the preliminary sacrificial layers are formed of polycrystalline silicon,
wherein the converting the preliminary sacrificial layers into sacrificial layers includes oxidizing the preliminary sacrificial layers by injecting oxygen through the channel holes, and
wherein the sacrificial layers are formed of a silicon oxide.

3. The method of manufacturing a semiconductor device of claim 1, wherein the preliminary sacrificial layers include a polymer, and
wherein the converting the preliminary sacrificial layers into sacrificial layers includes reacting an organic compound with the preliminary sacrificial layers by injecting the organic compound through the channel holes.

4. The method of manufacturing a semiconductor device of claim 1, wherein the preliminary sacrificial layers include a material having a lamellar structure, and wherein the sacrificial layers include an interlayer compound.

5. The method of manufacturing a semiconductor device of claim 1, wherein each of the sacrificial layers has a thickness that is reduced in a direction away from the channel holes.

6. The method of manufacturing a semiconductor device of claim 1, wherein each of the sacrificial layers has a thickness increased in a direction away from the channel holes.

7. The method of manufacturing a semiconductor device of claim 1, further comprising:
removing a portion of the sacrificial layers that protrude further towards the channel hole than a side surface of the mold insulating layers;
forming channel structures including a gate dielectric layer and a channel layer in the channel holes; and
replacing the sacrificial layers with gate electrodes.

8. The method of manufacturing a semiconductor device of claim 1, wherein the forming a preliminary stacked structure includes:
forming a first preliminary stacked structure including mold insulating layers and preliminary sacrificial layers on the substrate;
forming first preliminary channel holes passing through the first preliminary stacked structure;
forming a gap-fill layer filling the first preliminary channel holes; and
forming a second preliminary stacked structure including mold insulating layers and preliminary sacrificial layers on the first preliminary stacked structure.

9. The method of manufacturing a semiconductor device of claim 8, wherein the forming channel holes passing through the preliminary stacked structure includes:
forming second channel holes passing through the second preliminary stacked structure; and
removing the gap-fill layer through the second channel holes.

10. A method of manufacturing a semiconductor device, comprising:
alternately stacking first material layers and second material layers on a substrate;
forming channel holes passing through the first material layers and the second material layers; and
converting the first material layers and/or the second material layers into third material layers through the channel holes,
wherein the third material layers have thicknesses greater than thicknesses of the first material layers or the second material layers that were converted.

11. The method of manufacturing a semiconductor device of claim 10, further comprising:
converting the first material layers into third material layers having a volume greater than a volume of the first material layers using the channel holes; and
converting the second material layers into fourth material layers having a volume greater than a volume of the second material layers using the channel holes.

12. The method of manufacturing a semiconductor device of claim 11, wherein the first material layers are formed of polydimethylsiloxane (PDMS), and
wherein the converting the first material layers into third material layers includes injecting 1-bromododecane through the channel holes.

13. The method of manufacturing a semiconductor device of claim 11, wherein the second material layers are formed of polycrystalline silicon, and
wherein the converting the second material layers into fourth material layers includes injecting of oxygen through the channel holes.

14. The method of manufacturing a semiconductor device of claim 11, further comprising replacing the third material layers with fifth material layers formed of a silicon nitride.

15. The method of manufacturing a semiconductor device of claim 11, further comprising:
forming channel structures including a gate dielectric layer and a channel layer in the channel holes; and
replacing the fourth material layers with gate electrodes.

16. A semiconductor device, comprising:
a gate structure including mold insulating layers and gate electrodes alternately disposed on a substrate; and
channel structures in contact with the substrate through the gate structure,
wherein a side surface of the mold insulating layers, in contact with the channel structures, protrudes further in a horizontal direction than a side surface of the gate electrodes.

17. The semiconductor device of claim 16, wherein a length, by which a side surface of the mold insulating layers protrudes, is decreased in a direction towards the substrate.

18. The semiconductor device of claim 16, wherein a thickness of the mold insulating layers is decreased in a direction towards the channel structures.

19. The semiconductor device of claim 16, wherein thicknesses of the gate electrodes are increased in a direction towards the channel structures.

20. The semiconductor device of claim 16, wherein each of the gate electrodes includes a first conductive layer and a second conductive layer at least partially surrounded by the first conductive layer, and
wherein a thickness of the second conductive layer is increased in a direction towards the channel structures.
